(19) United States
(12) Patent Application Publication
(10) Pub. No.: US 2010/0059115 A1
(43) Pub. Date: Mar. 11, 2010

(54) Coated Substrates and Semiconductor Devices Including the Substrates

(75) Inventor: Benyamin Buller, Sylvania, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/553,354

(22) Filed: Sep. 3, 2009

Related U.S. Application Data
(60) Provisional application No. 61/094,602, filed on Sep. 5, 2008.

(51) Int. Cl. H01L 31/02; C23C 14/34; H01B 1/08; H01L 31/0232; H01L 31/0296

(52) U.S. Cl. 136/256; 204/192.1; 174/126.1; 136/252; 136/260

(57) ABSTRACT

A photovoltaic cell can include a substrate having a transparent conductive oxide layer and an antireflective layer. The layers can be deposited by sputtering or by chemical vapor deposition.

### CLAIM FOR PRIORITY

This application claims priority under 35 U.S.C. §119(e) to Provisional U.S. Patent Application Ser. No. 61/094,602 filed on Sep. 5, 2008, which is hereby incorporated by reference.

### TECHNICAL FIELD

This invention relates to coating techniques and coated substrates.

### BACKGROUND

Coated glass articles are known in the art. There are many techniques to apply layers to a glass article, including sputtering, chemical vapor deposition (CVD), physical vapor deposition (PVD), and other techniques. Sputtering can include a process where atoms are ejected from a solid target material due to bombardment of the target by energetic ions. In a typical CVD process, the substrate can be exposed to one or more volatile precursors, which react and/or decompose on the substrate surface to produce the desired deposited material. Frequently, volatile by-products are also produced, which are removed by gas flow through the reaction chamber.

It is desirable to coat both sides of a substrate. From a processing time and capital expenditure perspective, it is desirable to coat both sides of a substrate without passing the substrate through an apparatus multiple times. Accordingly, it can be seen that there exists a need in the art for an apparatus which is capable of coating both sides of a substrate without necessarily having to pass the substrate through the apparatus more than one time.

### SUMMARY

In general, a method of manufacturing an optical device substrate can include depositing an antireflective layer on a first surface of the substrate by chemical vapor deposition, and depositing a transparent conductive layer on a second surface of the substrate by sputtering. The optical device can be a CdTe thin film Photovoltaic device. The antireflective layer deposition may occur before the transparent conductive layer deposition, after the transparent conductive layer deposition, or substantially simultaneously with the transparent conductive layer deposition.

An optical device substrate can include a substrate, a sputtered transparent conductive layer in contact with a first surface of the substrate, and an antireflective layer in contact with a second surface of the substrate. In certain circumstances, a substrate can be a glass substrate. The optical device substrate can be used in a photovoltaic cell, and the photovoltaic cell can be a CdTe thin film photovoltaic device. The transparent conductive layer can be indium tin oxide.

An optical device substrate can include a substrate, a sputtered transparent conductive layer in contact with a first surface of the substrate, an active photovoltaic layer adjacent to the transparent conductive layer, and an antireflective layer in contact with a second surface of the substrate. In certain circumstances, a substrate can be a glass substrate. The optical device substrate can be used in a photovoltaic cell, and the photovoltaic cell can be a CdTe thin film photovoltaic device. The transparent conductive layer can be indium tin oxide.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic of a substrate with multiple layers.

FIG. 2 is a schematic of a two stage deposition system.

FIG. 3 is a schematic of a two stage deposition system.

FIG. 4 is a schematic of a single stage deposition system.

FIG. 5 is a schematic of a single stage deposition system.

### DETAILED DESCRIPTION

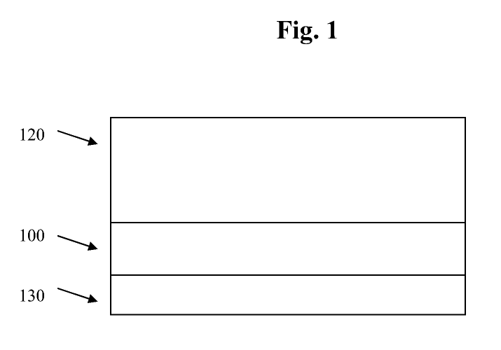

Referring to FIG. 1, a photovoltaic cell can include a transparent conductive layer 120. The transparent conductive layer 120 can be a transparent conductive oxide, which can include indium tin oxide, for example. The transparent conductive layer 120 is deposited on a substrate 100. The substrate 100 can be glass, for example. The photovoltaic cell can also include an antireflective layer 130 deposited on the other side of the substrate 100. The antireflective coating 130 can be a very thin, two layer stack. The transparent conductive oxide film 120 can be fluorine-doped tin oxide, aluminum-doped zinc oxide, or indium tin oxide, etc.

The antireflective coating can be applied to the substrate using chemical vapor deposition when the glass comes out of the annealing lehr during manufacture. Alternatively, the antireflective coating can be added by chemical vapor deposition during deposition of the semiconductor layers, or can be added after deposition of the semiconductor layers. Chemical vapor deposition can be, e.g., an atmospheric pressure chemical vapor deposition, low pressure chemical vapor deposition, or an ultrahigh vacuum chemical vapor deposition system. The antireflective coating can also be applied to the substrate using physical vapor deposition. Physical vapor deposition can involve purely physical processes such as high temperature vacuum evaporation or plasma sputter bombardment.

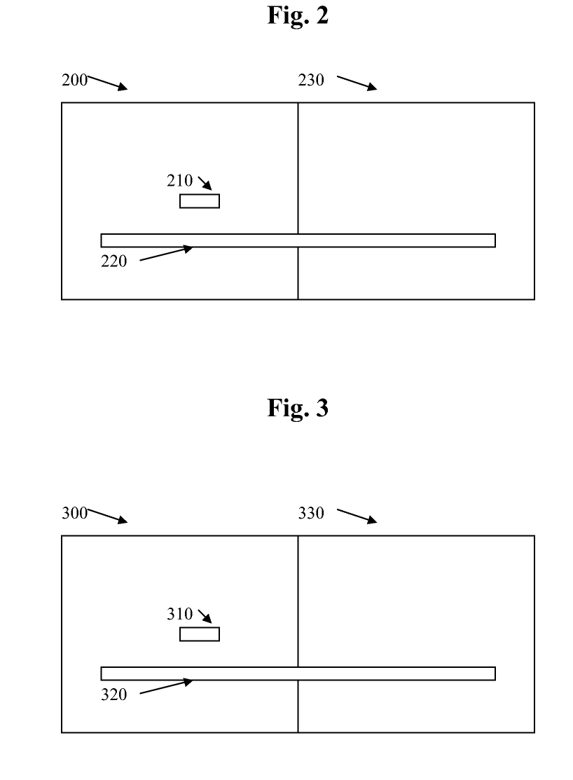

Referring to FIG. 2, a two stage system can include an initial chemical vapor deposition chamber 200 that deposits the antireflective coating onto a glass substrate 210. The substrate 210 travels through the initial chamber 200 on a conveyer 220. Next, a subsequent chamber 230 deposits a transparent conductive oxide layer on the substrate 210 using sputtering. The substrate 210 continues through the subsequent chamber 230 along the conveyer 220. Alternatively, the sputtering chamber 230 can be the initial chamber while the chemical vapor deposition chamber 200 can be the subsequent chamber.

Referring to FIG. 3, a two stage system can include an initial sputtering chamber 300 that deposits the antireflective coating onto a glass substrate 310. As above, the substrate 310 travels through the initial chamber 300 on a conveyer 320. Next, a subsequent chamber 330 deposits a transparent conductive oxide layer on the substrate 310 using sputtering. The substrate 310 continues through the subsequent chamber 330 along the conveyer 320. Alternatively, the transparent conductive oxide sputtering chamber 330 can be the initial chamber while the antireflective sputtering chamber 300 can be the subsequent chamber.

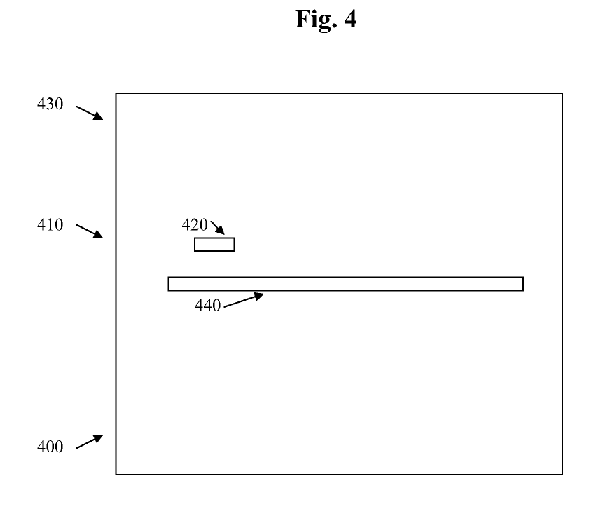

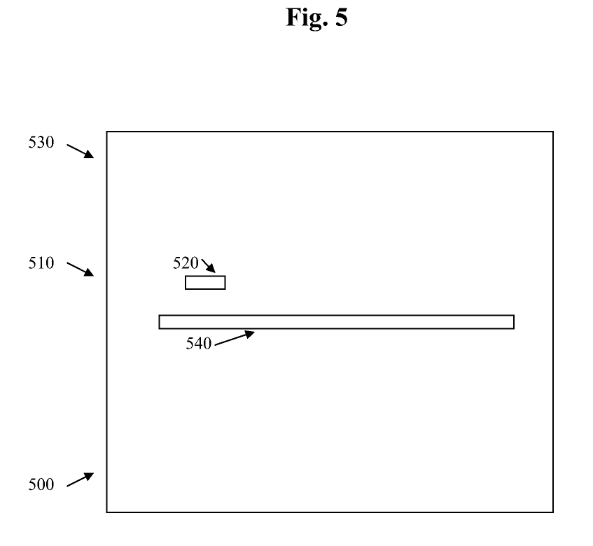

Referring to FIG. 4, a single stage system can include a lower chemical vapor deposition portion 400 of a chamber 410 that deposits the antireflective coating onto a glass substrate 420. An upper portion 430 of chamber 410 deposits a transparent conductive oxide layer on the substrate 420 using sputtering. The substrate 420 travels through the chamber 410 on a conveyer 440. Referring to FIG. 5, a single stage system can include a lower sputtering portion 500 of a chamber 510 that deposits the antireflective coating onto a glass substrate 520. An upper portion 530 of chamber 510 deposits a transparent conductive oxide layer on the substrate 520 using sputtering. The substrate 520 travels through the chamber 510 on a conveyer 540.

A common photovoltaic cell can have multiple layers. The multiple layers can include a bottom layer that is a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. A top substrate layer can be placed on top of the top layer to form a sandwich and complete the photovoltaic cell.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports each substrate into a series of one or more deposition stations for depositing layers of material on the exposed surface of the substrate. Conveyors are described in U.S. patent application Ser. No. 11/692,667 filed on Mar. 28, 2007, which is hereby incorporated by reference.

The deposition chamber can be heated to reach a processing temperature of not less than about 450° C. and not more than about 700° C., for example the temperature can range from 450-550° C., 550-650° C., 570-600° C., 600-640° C. or any other range greater than about 450° C. and less than about 700° C. The deposition chamber includes a deposition distributor connected to a deposition vapor supply. The distributor can be connected to multiple vapor supplies for deposition of various layers or the substrate can be moved through multiple and various deposition stations with its own vapor distributor and supply. The distributor can be in the form of a spray nozzle with varying nozzle geometries to facilitate uniform distribution of the vapor supply.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe. A top layer can cover the semiconductor layers. The top layer can include a metal such as, for example, aluminum, molybdenum, chromium, cobalt, nickel, titanium, tungsten, or alloys thereof. The top layer can also include metal oxides or metal nitrides or alloys thereof.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The transparent conductive layer can be a transparent conductive oxide, such as a metallic oxide like tin oxide, which can be doped with, for example, fluorine. This layer can be deposited between the front contact and the first semiconductor layer, and can have a resistivity sufficiently high to reduce the effects of pinholes in the first semiconductor layer. Pinholes in the first semiconductor layer can result in shunt formation between the second semiconductor layer and the first contact resulting in a drain on the local field surrounding the pinhole. A small increase in the resistance of this pathway can dramatically reduce the area affected by the shunt.

A capping layer can be provided to supply this increase in resistance. The capping layer can be a very thin layer of a material with high chemical stability. The capping layer can have higher transparency than a comparable thickness of semiconductor material having the same thickness. Examples of materials that are suitable for use as a capping layer include silicon dioxide, dialuminum trioxide, titanium dioxide, diboron trioxide, and other similar entities. The capping layer can also serve to isolate the transparent conductive layer electrically and chemically from the first semiconductor layer preventing reactions that occur at high temperature that can negatively impact performance and stability. The capping layer can also provide a conductive surface that can be more suitable for accepting deposition of the first semiconductor layer. For example, the capping layer can provide a surface with decreased surface roughness.

The first semiconductor layer can serve as a window layer for the second semiconductor layer. The first semiconductor layer can be thinner than the second semiconductor layer. By being thinner, the first semiconductor layer can allow greater penetration of the shorter wavelengths of the incident light to the second semiconductor layer.

The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures or alloys thereof. It can be a binary semiconductor, for example it can be CdS. The second semiconductor layer can be deposited onto the first semiconductor layer. The second semiconductor can serve as an absorber layer for the incident light when the first semiconductor layer is serving as a window layer. Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, TlN, TlP, TlAs, TlSb, or mixtures thereof.

The second semiconductor layer can be deposited onto a first semiconductor layer. A capping layer can serve to isolate a transparent conductive layer electrically and chemically from the first semiconductor layer preventing reactions that occur at high temperature that can negatively impact performance and stability. The transparent conductive layer can be deposited over a substrate.

A number of embodiments have been described. Nevertheless, it will be understood that various modifications may be made without departing from the spirit and scope of the invention. For example, the semiconductor layers can include a variety of other materials, as can the materials used for the buffer layer and the capping layer. Accordingly, other embodiments are within the scope of the following claims.

What is claimed is:

1. A method of manufacturing an optical device substrate comprising:
depositing an antireflective layer on a first surface of the substrate by chemical vapor deposition; and
depositing a transparent conductive layer on a second surface of the substrate by sputtering.

2. The method of claim 1, wherein the substrate comprises glass.

3. The method of claim 1, wherein the optical device is a CdTe thin film Photovoltaic device.

4. The method of claim 1, wherein the transparent conductive layer comprises CdTe.

5. The method of claim 1, wherein the step of depositing an antireflective layer occurs before the step of depositing a transparent conductive layer.

6. The method of claim 1, wherein the step of depositing an antireflective layer occurs after the step of depositing a transparent conductive layer.

7. The method of claim 1, wherein the step of depositing an antireflective layer occurs substantially simultaneously with the step of depositing a transparent conductive layer.

8. The method of claim 1, wherein the step of depositing an antireflective layer comprises atmospheric pressure chemical vapor deposition.

9. An optical device substrate comprising:
a substrate;
a sputtered transparent conductive layer in contact with a first surface of the substrate; and
an antireflective layer in contact with a second surface of the substrate.

10. The optical device substrate of claim 9, wherein the optical device substrate forms a photovoltaic device.

11. The optical device substrate of claim 10, wherein the photovoltaic device is a thin film photovoltaic device.

12. The optical device substrate of claim 10, wherein the photovoltaic device is a CdTe thin film photovoltaic device.

13. The optical device substrate of claim 9, wherein the transparent conductive layer is indium tin oxide.

14. An optical device substrate comprising:
a substrate;
a sputtered transparent conductive layer in contact with a first surface of the substrate;
an active photovoltaic layer adjacent to the transparent conductive layer; and
an antireflective layer in contact with a second layer of the substrate.

15. The optical device substrate of claim 14, wherein the optical device substrate forms a photovoltaic device.

16. The optical device substrate of claim 15, wherein the photovoltaic device is a thin film photovoltaic device.

17. The optical device substrate of claim 15, wherein the photovoltaic device is a CdTe thin film photovoltaic device.

18. The optical device substrate of claim 14, wherein the transparent conductive layer is indium tin oxide.
